(19) United States
(12) Patent Application Publication
(10) Pub. No.: US 2020/0251496 A1
(43) Pub. Date: Aug. 6, 2020

(54) PROGRAMMABLE INTEGRATED CIRCUIT AND CONTROL DEVICE

(71) Applicant: NEC Corporation, Minato-ku, Tokyo (JP)

(72) Inventors: Makoto MIYAMURA, Tokyo (JP); Toshitsugu SAKAMOTO, Tokyo (JP); Yukihide TSUJI, Tokyo (JP); Ryusuke NEBASHI, Tokyo (JP); Ayuka TADA, Tokyo (JP); Xu BAI, Tokyo (JP)

(73) Assignee: NEC Corporation, Minato-ku, Tokyo (JP)

(21) Appl. No.: 16/648,757

(22) PCT Filed: Sep. 14, 2018
(86) PCT No.: PCT/JP2018/034151

§ 371 Date: Mar. 19, 2020

(30) Foreign Application Priority Data
Sep. 22, 2017 (JP) 2017-182576

(51) Int. Cl. H01L 27/118; G11C 11/56; G11C 13/00; G06F 30/327

(52) U.S. Cl. CPC H01L 27/11807; G11C 11/5614; H01L 2027/11883; G06F 30/327; G11C 13/0011

(57) ABSTRACT

A programmable integrated circuit includes: a crossbar switch constituted of a plurality of first wires arranged in a first direction, a plurality of second wires arranged in a second direction intersecting the first direction, and resistance change type elements connecting the first wires and the second wires; an output buffer group constituted of at least two output buffers operating with different drive powers; and a logic circuit group constituted of at least one logic circuit connected to an output of the second wire. The output buffers in the output buffer group is connected to an input of any one of a plurality of the first wires.

### TECHNICAL FIELD

The present invention relates to a programmable integrated circuit and a control device. Particularly, the present invention relates to a programmable integrated circuit using a resistance change type non-volatile element, and a control device which sets configuration data in the programmable integrated circuit.

### BACKGROUND ART

Along with miniaturization of a semiconductor integrated circuit, an electric field transistor has increased in integration at a pace being four times in three years. As a result, a photomask needed for manufacture of an integrated circuit, and design inspection cost for a circuit have increased, and development cost for an application specific integrated circuit (ASIC) for which a user custom-designs a fixed function in advance has increased. Under such circumstances, attention is being drawn to a semiconductor device with which a designer can electrically program a desired circuit into a manufactured semiconductor chip, such as a field programmable gate array (FPGA).

An FPGA has a programmable wire (hereinafter, also referred to as a crossbar switch) as a main component, in order to enable implementation of a user design described in a resistor transfer level (RTL) language. A crossbar switch using a complementary metal-oxide-semiconductor (CMOS) circuit, an antifuse type element, or a resistance change type element can be cited as an example of a crossbar switch.

A crossbar switch using a CMOS circuit includes, as basic components, a static random access memory (SRAM) storing a connection state of a wire, and a pass transistor on/off of which is controlled by a switch control signal stored in the SRAM. While a crossbar switch using a CMOS circuit is easy in terms of a manufacturing process, an FPGA using a CMOS circuit requires a great number of transistors for one changeover switch. Accordingly, there is a problem that a layout area when being integrated on a semiconductor wafer increases, and thus leads to limitation on cost and performance.

NPL 1 discloses one example of a crossbar switch using a CMOS circuit. In the crossbar switch in NPL 1, a pass transistor is disposed in a shape of a tournament. Thus, an FPGA using the crossbar switch in NPL 1 increases in layout area to a proportionality relation or more as a circuit becomes large-scale, and therefore, it is difficult to configure a large-scale crossbar switch.

PTL 1 discloses a crossbar switch using an antifuse type element.

In a crossbar switch using a resistance change type element, a basic component of a connection switch is only the resistance change type element. Thus, a crossbar switch using a resistance change type element is complicated in terms of a manufacturing process, but can keep down an increase in layout area when being integrated, if an element size is equally small as compared with a CMOS. For example, as one example of a resistance change type element, a resistance random access memory (ReRAM) using a transition metal oxide, Nano Bridge (registered trademark) using an ionic conductor, and the like can be cited.

PTL 2 discloses a resistance change type element which changes a resistance value of an ionic conductor by altering an applied voltage polarity, and controls a conduction state between two electrodes. PTL 2 discloses a crossbar switch using the resistance change type element for ultra-large scale integration (ULSI).

FIG. 25 is a configuration example of a crossbar switch of an FPGA using the resistance change type element in PTL 2. A crossbar switch 100 in FIG. 25 has a configuration in which a resistance change type element 103 is disposed at an intersection of a plurality of input lines 101 and a plurality of output lines 102. Since the configuration of the crossbar switch 100 is simple as in FIG. 25, a multiple-input and multiple-output crossbar switch can be relatively easily configured.

FIG. 26 is a crossbar switch circuit in which logic circuits (logic circuits 106a to c) are connected to the output line 102 of the crossbar switch 100 (FIG. 25) using the resistance change type element in PTL 2. When the resistance change type element 103 is in an on-state, a capacity 104 of each of the output lines 102 and an input capacity 105 to the logic circuit 106 are connected as a load to each of the input lines 101. Note that, in FIG. 26, the resistance change type element 103 (resistance change type elements 103a to d) in an on-state is filled in black, and the resistance change type element 103 in an off-state is filled in white.

In FIG. 26, one output line 102b is connected to the input line 101a via the resistance change type element 103a in an on-state. Moreover, the output line 102a, the output line 102c, and the output line 102d are each connected to the input line 101b via each of the resistance change type elements 103b to d in an on-state. Hereinafter, a number of the output lines 102 connected to the input line 101 is referred to as a fan-out number. In the example of FIG. 26, a fan-out number of the input line 101a is 1, and a fan-out number of the input line 101b is 3.

As in FIG. 26, the capacity 104b and the input capacity 105b are connected as a load to the input line 101a via the resistance change type element 103a. Moreover, a load combining three capacities (the capacity 104a, the capacity 104c, and the capacity 104d) and three input capacities (the input capacity 105a, the input capacity 105c, and the input capacity 105d) is connected to the input line 101b via each of the resistance change type elements 103b to d.

Furthermore, PTL 3 discloses a resistance change type element utilizing movement and an electrochemical reaction of a metallic ion in an ionic conductor in which an ion can freely move by application of an electric field. PTL 3 discloses a method of achieving both off-reliability and writing at a low voltage by serially connecting resistance change type elements and thus utilizing the resistance change type elements as a unit element.

### CITATION LIST

### Patent Literature

[PTL 1] Specification of U.S. Pat. No. 5,537,056
[PTL 2] Japanese Unexamined Patent Application Publication No. 2005-101535
[PTL 3] International Publication No. WO2013/190741

### Non Patent Literature

[NPL 1] I. Kuon et al., “FPGA Architecture: Survey and Challenges”, Foundations and Trends in Electronic Design Automation, Vol. 2, Issue 2, February, 2008, pp. 135 to 253

### SUMMARY OF INVENTION

### Technical Problem

In a crossbar switch circuit using the resistance change type element in PTL 2, a capacity of an output line, and an input capacity of a subsequent-stage logic circuit become large as a fan-out number is greater. Thus, the crossbar switch circuit using the resistance change type element in PTL 2 has a problem that a propagation delay of a signal increases as a fan-out number is greater when input of a crossbar switch is driven with an equal current value.

Furthermore, the crossbar switch circuit using the resistance change type element in PTL 2 is advantageous to a larger scale in respect of a layout area, but changes in propagation delay depending on a fan-out number of a crossbar. When being set assuming a case with a slowest propagation delay, the crossbar switch circuit deteriorates in delay performance as a circuit. In order to increase drive current, an area of a buffer circuit which drives the crossbar switch is increased, and an area of a crossbar switch circuit becomes large. Moreover, when drive current of a crossbar switch input is increased assuming a case with a slowest propagation delay, large pulse current instantaneously flows in a resistance change type element of a crossbar switch having a small fan-out number. There is a possibility that stress resulting from electromigration increases in a resistance change type element in which large pulse current instantaneously flows.

In order to solve the problem described above, an object of the present invention is to provide a programmable logic circuit which can reduce a propagation delay and electromigration that can occur depending on a fan-out number, in a crossbar switch circuit using a resistance change type element.

### Solution to Problem

A programmable logic circuit according to one aspect of the present invention includes: a crossbar switch constituted of a plurality of first wires arranged in a first direction, a plurality of second wires arranged in a second direction intersecting the first direction, and resistance change type elements connecting the first wires and the second wires; a logic circuit group constituted of at least one logic circuit connected to an output of the second wires; and an output buffer group constituted of at least two output buffers being connected to inputs of the first wires and operating with different drive powers.

A control device according to one aspect of the present invention programs a user circuit into a programmable integrated circuit. The programmable integrated circuit includes a crossbar switch, an output buffer connected to an input of the crossbar switch and having at least two variable drive powers, and at least one logic circuit connected to any one of outputs of the crossbar switch, and has a configuration in which an output of the logic circuit is fed back to any one of the output buffers. And the control circuit includes: an input means which inputs a behavioral description file of the user circuit; a logic synthesis means which generates a first-level net list by logically synthesizing a behavioral description file; a mapping means which converts the first-level net list into a second-level net list by mapping the first-level net list; a cluster means which groups a plurality of logic elements included in the second-level net list, and generates a third-level net list adapted to a configuration of clustered basic logic elements; a layout means which generates configuration information of the user circuit by calculating optimum disposition of the third-level net list for an array of the clustered basic logic elements, connecting the crossbar switch connected to the clustered basic logic elements, and then performing wiring inside and outside a cluster; a storage means which stores a reference table saving a value of a drive power of the output buffer associated with a fan-out number of the crossbar switch; a drive power determination means which calculates the fan-out number for each input of the crossbar switch, based on the configuration information of the user circuit, and determines a drive power of the output buffer associated with the fan-out number by referring to the reference table; a data generation means which generates configuration data for programming the user circuit into the programmable integrated circuit, based on the configuration information of the user circuit including a drive power of the output buffer; and a circuit setting means which programs the user circuit into the programmable integrated circuit, based on the configuration data.

A control device according to one aspect of the present invention programs a user circuit into a programmable integrated circuit. The programmable integrated circuit includes a crossbar switch, an output buffer connected to an input of the crossbar switch and having at least two fixed drive powers, and at least one logic circuit connected to any one of outputs of the crossbar switch, and has a configuration in which an output of the logic circuit is fed back to any one of the output buffers. And the control circuit includes: an input means which inputs a behavioral description file of the user circuit; a logic synthesis means which generates a first-level net list by logically synthesizing the behavioral description file; a mapping means which converts the first-level net list into a second-level net list by mapping the first-level net list; a cluster means which groups a plurality of logic elements included in the second-level net list, and generates a third-level net list adapted to a configuration of clustered basic logic circuits; an allocation means which re-clusters the basic logic circuit by calculating a fan-out number for each input of the crossbar switch, based on the third-level net list, and allocates the output buffers having high drive powers to an input of the crossbar switch in a descending order of fan-out numbers; a layout means which generates configuration information of the user circuit by calculating optimum disposition of the third-level net list for an array of the re-clustered basic logic circuits, connects the crossbar switch connected to the re-clustered basic logic circuits, and then performs wiring inside and outside a cluster; a data generation means which generates configuration data for programming the user circuit into the programmable integrated circuit, based on the configuration information of the user circuit including allocation of the output buffers; and a circuit setting means which programs the user circuit into the programmable integrated circuit, based on the configuration data.

### Advantageous Effects of Invention

According to the present invention, it becomes possible to provide a programmable logic circuit which can reduce a propagation delay and electromigration that can occur depending on a fan-out number, in a crossbar switch circuit using a resistance change type element.

### BRIEF DESCRIPTION OF DRAWINGS

FIG. 1 is a conceptual diagram illustrating a configuration of a programmable logic circuit according to a first example embodiment of the present invention.

FIG. 2 is a conceptual diagram illustrating a configuration of the programmable logic circuit according to the first example embodiment of the present invention.

FIG. 3 is a conceptual diagram illustrating one example of a circuit configuration of a programmable output buffer provided in the programmable logic circuit according to the first example embodiment of the present invention.

FIG. 4 is a truth table of a buffer circuit included in the programmable output buffer provided in the programmable logic circuit according to the first example embodiment of the present invention.

FIG. 5 is a truth table of a tristate buffer circuit included in the programmable output buffer provided in the programmable logic circuit according to the first example embodiment of the present invention.

FIG. 6 is a table compiling drive powers for set values of an enable terminal of the programmable output buffer provided in the programmable logic circuit according to the first example embodiment of the present invention.

FIG. 7 is a symbol of a bipolar type element being one example of a resistance change type element constituting a crossbar switch provided in the programmable logic circuit according to the first example embodiment of the present invention.

FIG. 8 is a symbol of a unipolar type element being one example of a resistance change type element constituting a crossbar switch provided in the programmable logic circuit according to the first example embodiment of the present invention.

FIG. 9 is a symbol of an element in which two bipolar type elements are serially connected with reverse polarity, as one example of a resistance change type element constituting a crossbar switch provided in the programmable logic circuit according to the first example embodiment of the present invention.

FIG. 10 is a conceptual diagram for describing a capacity of an output line and an input capacity of a logic circuit provided in the programmable logic circuit according to the first example embodiment of the present invention.

FIG. 11 is a conceptual diagram for describing a connection relation between the programmable logic circuit according to the first example embodiment of the present invention and a logic circuit of a previous-stage circuit.

FIG. 12 is a conceptual diagram illustrating a configuration of a modification example of the programmable logic circuit according to the first example embodiment of the present invention.

FIG. 13 is a conceptual diagram illustrating a configuration of a programmable logic circuit (cluster structure) according to a second example embodiment of the present invention.

FIG. 14 is a conceptual diagram illustrating a configuration of a programmable logic circuit in which cluster structures according to the second example embodiment of the present invention are arranged in an array form.

FIG. 15 is a conceptual diagram illustrating a configuration example of a switch box included in a programmable logic circuit in which cluster structures according to the second example embodiment of the present invention are arranged in an array form.

FIG. 16 is a conceptual diagram illustrating another configuration example of a switch box included in a programmable logic circuit in which cluster structures according to the second example embodiment of the present invention are arranged in an array form.

FIG. 17 is a conceptual diagram illustrating a configuration of a programmable logic circuit according to a third example embodiment of the present invention.

FIG. 18 is a conceptual diagram illustrating a configuration of a programmable logic circuit according to a fourth example embodiment of the present invention.

FIG. 19 is a conceptual diagram illustrating a configuration of a semiconductor device according to a fifth example embodiment of the present invention.

FIG. 20 is a block diagram illustrating a configuration of a control device according to a sixth example embodiment of the present invention.

FIG. 21 is a flowchart for describing an operation of the control device according to the sixth example embodiment of the present invention.

FIG. 22 is a block diagram illustrating a configuration of a control device according to a seventh example embodiment of the present invention.

FIG. 23 is a flowchart for describing an operation of the control device according to the seventh example embodiment of the present invention.

FIG. 24 is a block diagram illustrating one example of a hardware configuration which achieves the control device according to each of the sixth and seventh example embodiments of the present invention.

FIG. 25 is a conceptual diagram illustrating a configuration of a general crossbar switch including a resistance change type element.

FIG. 26 is a conceptual diagram for describing a problem of a general crossbar switch including a resistance change type element.

### EXAMPLE EMBODIMENT

Example embodiments of the present invention will be described below by use of the drawings. However, limitation being technically preferable in order to implement the present invention is placed on the example embodiments described below, but does not limit the scope of the invention to the description below. Note that, in all the drawings used for description of the example embodiments below, the same reference sign may be given to a similar part, and a reference sign may be omitted, unless there is particularly a reason. Moreover, in the example embodiments below, repeated description may be omitted in relation to similar configuration and operation.

### First Example Embodiment

First, a programmable logic circuit according to a first example embodiment of the present invention is described with reference to the drawings.

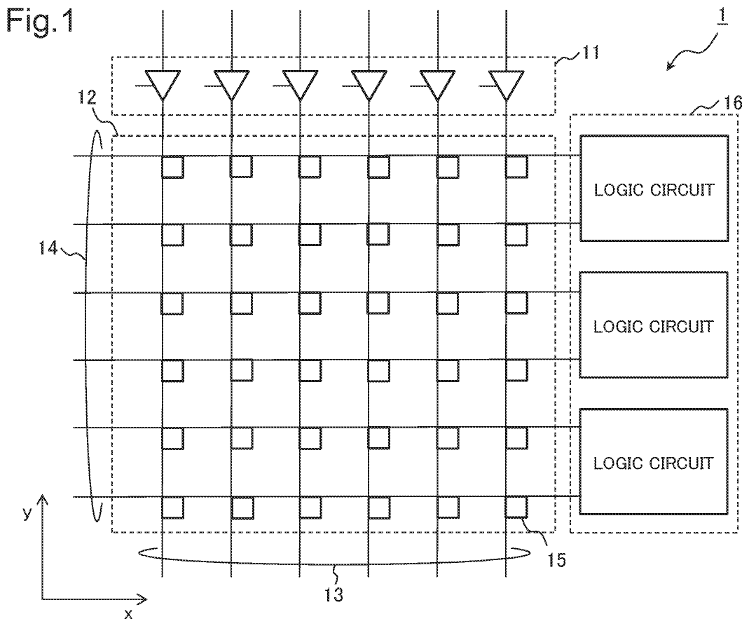

FIG. 1 is a conceptual diagram illustrating a configuration of a programmable logic circuit 1 according to the present example embodiment. As in FIG. 1, the programmable logic circuit 1 includes an output buffer group 11, a crossbar switch 12, and a logic circuit group 16.

The output buffer group 11 includes at least one output buffer. A drive power of an output buffer included in the output buffer group 11 is set according to a number (also referred to as a fan-out number) of output lines 14 being connection destinations of an input line connected to the output buffer.

The output buffer group 11 includes a plurality of output buffers which can drive with drive powers being different from each other. The present example embodiment cites an example using a program output buffer in which a drive power can be set. For example, a program output buffer includes at least one buffer circuit, and at least one tristate buffer circuit.

The crossbar switch 12 is constituted of an input line 13 laid along a y-direction (also referred to as a first direction), an output line 14 laid along an x-direction (also referred to as a second direction), and a resistance change type element 15 placed at an intersection of the input line 13 and the output line 14. The present example embodiment describes an example in which the crossbar switch 12 is constituted of a plurality of input lines 13, a plurality of output lines 14, and a plurality of resistance change type elements 15.

The input line 13 (also referred to as a first wire) is connected to any one of the output buffers included in the output buffer group 11. Moreover, the input line 13 is connected to the output line 14 via the resistance change type element 15. Note that, in the present example embodiment, the input line 13 is described in this way, regardless of whether the line is a single line or a multiple line.

The output line 14 (also referred to as a second wire) is connected to the input line 13 via the resistance change type element 15. Moreover, the output line 14 is connected to any one of logic circuits constituting the logic circuit group 16. Note that, in the present example embodiment, the output line 14 is described in this way, regardless of whether the line is a single line or a multiple line.

The resistance change type element 15 is placed at an intersection of the input line 13 and the output line 14. An on/off-state of the resistance change type element 15 is controlled by a non-illustrated control line. When the resistance change type element 15 is in an on-state, the input line 13 and the output line 14 are connected to each other, and a signal input from any one of the output buffers of the output buffer group 11 is output to any one of the logic circuits constituting the logic circuit group 16. On the other hand, when the resistance change type element 15 is in an off-state, the input line 13 and the output line 14 are not connected to each other, and a signal input from the output buffer group 11 is not output to the logic circuit group 16.

The logic circuit group 16 includes at least one logic circuit. The logic circuit included in the logic circuit group 16 is a circuit set in such a way as to perform various logic operations. The logic circuit included in the logic circuit group 16 is connected to any one of the output lines 14. The logic circuit to which a signal is input via the resistance change type element 15 in an on-state executes a logic operation in relation to the input signal, and outputs an execution result.

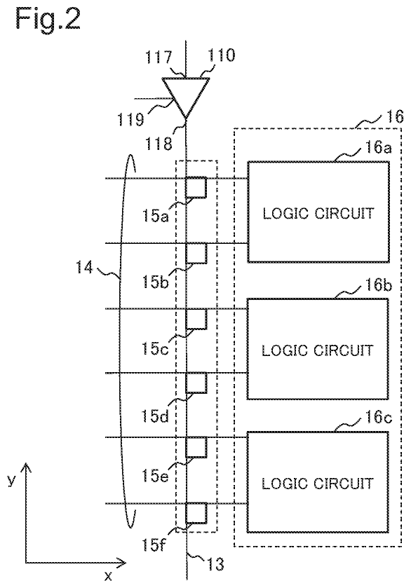

FIG. 2 is a conceptual diagram in which a partial configuration of the programmable logic circuit 1 is extracted, in order to describe the output buffer group 11 included in the programmable logic circuit 1. FIG. 2 illustrates one (a programmable output buffer 110) of the plurality of output buffers included in the output buffer group 11.

As in FIG. 2, the programmable output buffer 110 includes an input terminal 117, an output terminal 118, and a drive power setting terminal 119. The input terminal 117 is connected to an output of any one of the logic circuits constituting the previous-stage logic circuit group 16. The output terminal 118 is connected to one end of the input line 13. The drive power setting terminal 119 is connected to a non-illustrated control device, and inputs a control signal for setting a drive power of the programmable output buffer 110. A drive power of the programmable output buffer 110 is set according to a control signal.

For example, it is assumed that a resistance change type element 15a is in an on-state, and resistance change type elements 15b to f are in an off-state. In this case, a signal input to the input line 13 from the programmable output buffer 110 is input to a logic circuit 16a via the resistance change type element 15a in an on-state and the output line 14. In this instance, since a fan-out number of the input line 13 connected to the programmable output buffer 110 is 1, a drive power of the programmable output buffer 110 is set to 1 time.

Furthermore, for example, it is assumed that the resistance change type elements 15a to c are in an on-state, and the resistance change type elements 15d to f are in an off-state. In this case, a signal input to the input line 13 from the programmable output buffer 110 is input to the logic circuits 16a and b via the resistance change type elements 15a to c in an on-state and the output line 14. In this instance, since a fan-out number of the input line 13 connected to the programmable output buffer 110 is 3, a drive power of the programmable output buffer 110 is set to 3 times.

In this way, in the present example embodiment, according to a fan-out number of an input line 13, a drive power of the programmable output buffer 110 connected to the input line 13 is set.

### [Programmable Output Buffer Circuit]

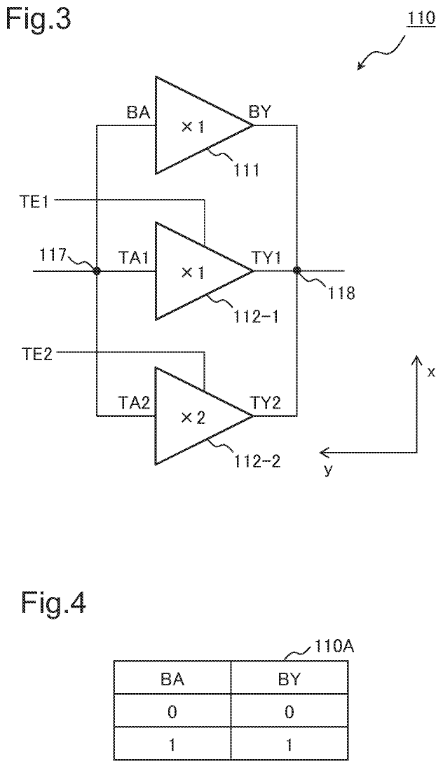

Next, a circuit configuration of the programmable output buffer 110 is described by citing one example. FIG. 3 is a circuit configuration being one example of the programmable output buffer 110. Note that FIG. 3 is one example of the circuit configuration of the programmable output buffer 110, and does not limit the circuit configuration of the programmable output buffer 110.

As in FIG. 3, the programmable output buffer 110 includes a buffer circuit 111, a tristate buffer circuit 112-1, and a tristate buffer circuit 112-2. Hereinafter, the tristate buffer circuit 112-1 and the tristate buffer circuit 112-2 may be described as a tristate buffer circuit 112 without being distinguished from each other.

The buffer circuit 111 includes an input terminal BA and an output terminal BY. The tristate buffer circuit 112-1 includes an input terminal TA1, an output terminal TY1, and an enable terminal TEL The tristate buffer circuit 112-2 includes an input terminal TA2, an output terminal TY2, and an enable terminal TE2.

The input terminal BA of the buffer circuit 111, the input terminal TA1 of the tristate buffer circuit 112-1, and the input terminal TA2 of the tristate buffer circuit 112-2 are connected to the input terminal 117. Moreover, the output terminal BY of the buffer circuit 111, the output terminal TY1 of the tristate buffer circuit 112-1, and the output terminal TY2 of the tristate buffer circuit 112-2 are connected to the output terminal 118. In other words, the programmable output buffer 110 has a configuration in which the buffer circuit 111, the tristate buffer circuit 112-1, and the tristate buffer circuit 112-2 are connected in parallel.

A control signal for setting a drive power of the tristate buffer circuit 112-1 is input to the enable terminal TE1 of the tristate buffer circuit 112-1. A drive power of the tristate buffer circuit 112-1 is set to 0 or 1 time depending on a setting signal.

A control signal for setting a drive power of the tristate buffer circuit 112-2 is input to the enable terminal TE2 of the tristate buffer circuit 112-2. A drive power of the tristate buffer circuit 112-2 is set to 0 or 2 times depending on a setting signal.

FIG. 4 is a truth table 110A of the buffer circuit 111. In other words, the buffer circuit 111 outputs 0 from the output terminal BY when 0 is input from the input terminal BA, and outputs 1 from the output terminal BY when 1 is input from the input terminal BA.

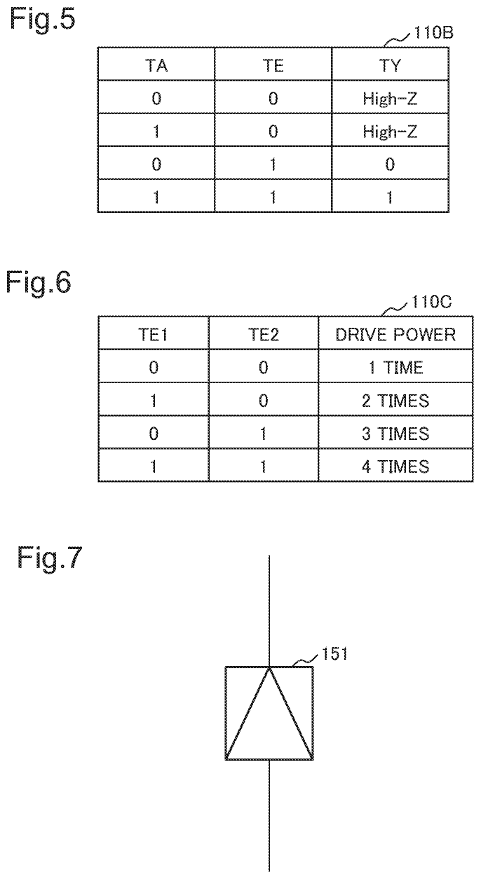

FIG. 5 is a truth table 110B of the tristate buffer circuit 112. In other words, when the enable terminal TE is set to 0, the output terminal TY is brought into a high-impedance state (high-Z), and the tristate buffer circuit 112 does not output any signal, even though either one of 0 and 1 is input from the input terminal TA. On the other hand, when the enable terminal TE is set to 1, the tristate buffer circuit 112 outputs 0 from the output terminal TY when 0 is input from the input terminal TA, and outputs 1 from the output terminal TY when 1 is input from the input terminal TA.

FIG. 6 is a table 110C compiling drive powers of the programmable output buffer 110 relevant to set values of the enable terminal TE1 and the enable terminal TE2.

When the enable terminal TE1 is set to 0, and the enable terminal TE2 is set to 0, outputs of the tristate buffer circuit 112-1 and the tristate buffer circuit 112-2 are separated, and a drive power becomes only a drive power of the buffer circuit 111. In other words, a drive power of the programmable output buffer 110 becomes 1 time.

When the enable terminal TE1 is set to 1, and the enable terminal TE2 is set to 0, an output of the tristate buffer circuit 112-2 is separated, and a drive power becomes a total of drive powers of the buffer circuit 111 and the tristate buffer circuit 112-1. In other words, a drive power of the programmable output buffer 110 becomes 2 times.

When the enable terminal TE1 is set to 0, and the enable terminal TE2 is set to 1, an output of the tristate buffer circuit 112-1 is separated, and a drive power becomes a total of drive powers of the buffer circuit 111 and the tristate buffer circuit 112-2. In other words, a drive power of the programmable output buffer 110 becomes 3 times.

When the enable terminal TE1 is set to 1, and the enable terminal TE2 is set to 1, a drive power becomes a total of drive powers of the buffer circuit 111, the tristate buffer circuit 112-1, and the tristate buffer circuit 112-2. In other words, a drive power of the programmable output buffer 110 becomes 4 times.

As described above, the programmable output buffer 110 is set to a drive power relevant to a set value of a control signal to which the enable terminal TE is set.

### [Resistance Change Type Element]

Herein, a specific example of the resistance change type element 15 is described by citing an example.

FIG. 7 is a symbolic representation of a unipolar type resistance change type element (a unipolar type element 151). The unipolar type element 151 has a configuration in which a resistance change layer is interposed between a first electrode and a second electrode. The unipolar type element 151 is a switching element which is switched between an off-state (a high-resistance state) and an on-state (a low-resistance state) by an applied voltage value.

When positive voltage is applied to the first electrode of the unipolar type element 151, and the applied voltage exceeds a predetermined set voltage, the unipolar type element 151 shifts from an off-state to an on-state. When larger voltage than reset voltage is applied to the unipolar type element 151 in an on-state, the unipolar type element 151 shifts from an on-state to an off-state. Further, when the applied positive voltage is increased and thus a voltage value exceeds the set voltage, the unipolar type element 151 again shifts from an off-state to an on-state.

On the other hand, when negative voltage is applied to the first electrode of the unipolar type element 151, and the voltage value exceeds the set voltage, the unipolar type element 151 shifts from an off-state to an on-state. When the negative voltage value applied to the first electrode of the unipolar type element 151 in an on-state exceeds the reset voltage, the unipolar type element 151 shifts from an on-state to an off-state. Further, when a negative voltage value applied to the first electrode of the unipolar type element 151 exceeds the set voltage, the unipolar type element 151 again shifts from an off-state to an on-state.

In this way, the unipolar type element 151 does not depend on polarity of voltage to be applied, and shows a resistance change characteristic dependent on an applied voltage value.

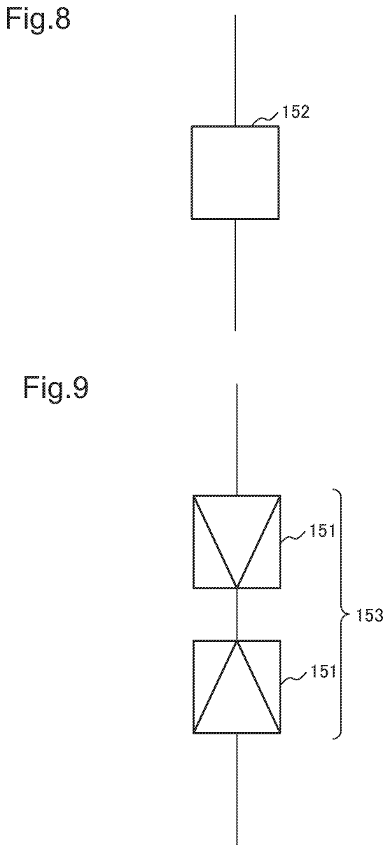

FIG. 8 is a symbolic representation of a bipolar type resistance change type element (a bipolar type element 152). The bipolar type element 152 has a configuration in which an ionic conductor functioning as a resistance change layer is interposed between a first electrode and a second electrode. The bipolar type element 152 is a switching element which is switched between an off-state and an on-state, according to polarity of applied voltage. Note that, in the bipolar type element 152, polarity is assumed to be positive polarity when the voltage applied to the first electrode is higher than the voltage applied to the second electrode.

When positive voltage is applied to the first electrode of the bipolar type element 152, and the applied voltage value exceeds the set voltage, the bipolar type element 152 shifts from an off-state to an on-state. On the other hand, when negative voltage is applied to the first electrode of the bipolar type element 152, and the applied voltage value exceeds the set voltage, the bipolar type element 152 shifts from an on-state to an off-state.

In this way, the bipolar type element 152 is switched between an off-state and an on-state, according to polarity of applied voltage.

In the present example embodiment, either one of the unipolar type element 151 and the bipolar type element 152 may be used. Moreover, as in FIG. 9, in order to enhance reliability of a switch, two bipolar type elements 152 may be serially connected with reverse polarity, and a resistance change type element 153 may be used.

### [Crossbar Switch]

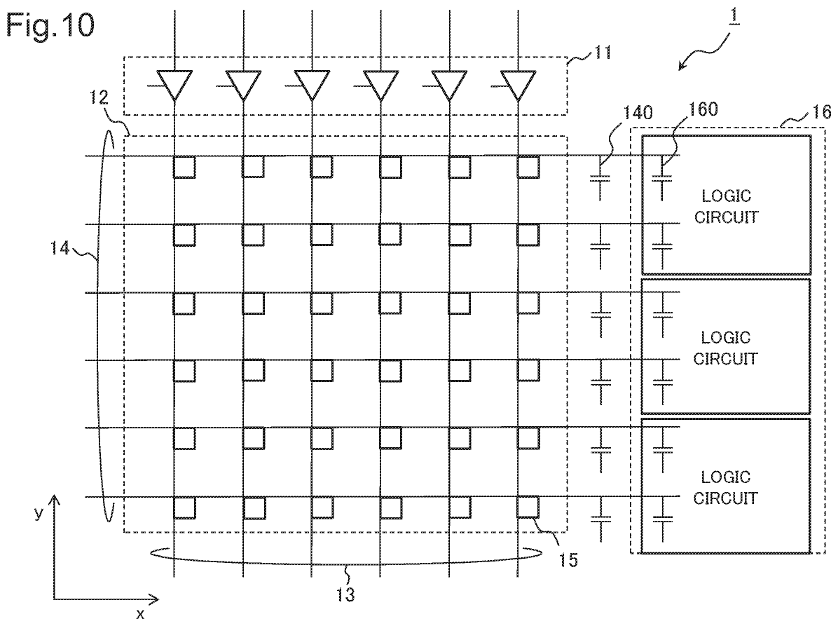

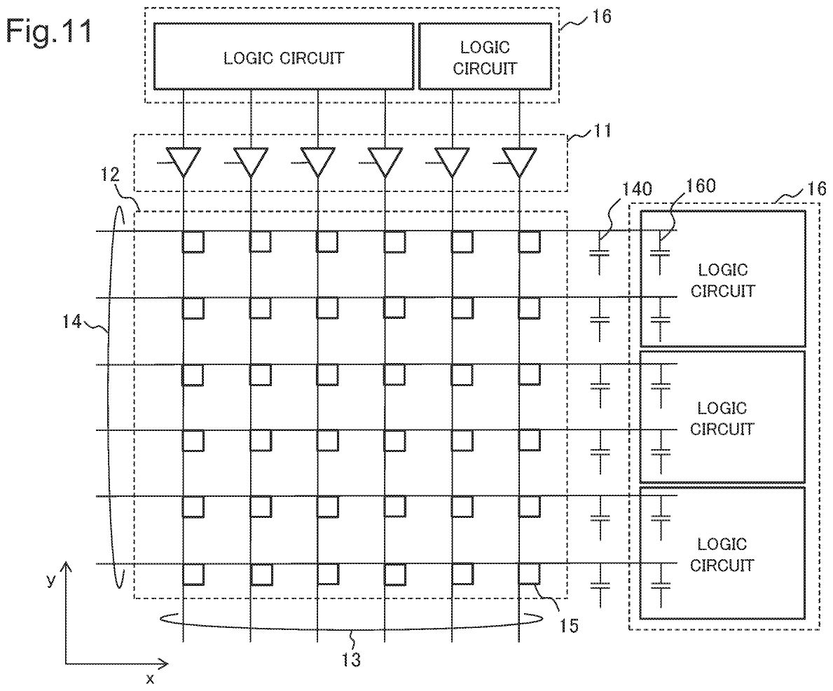

FIG. 10 is a conceptual diagram for describing capacities of the output line 14 and the logic circuit group 16 of the crossbar switch 12 in FIG. 1.

When any one of the resistance change type elements 15 connected to the input line 13 is in an on-state, the input line 13 is connected to any one of the output lines 14 via the resistance change type element 15 in an on-state. In this instance, a capacity 140 of the output line 14, and an input capacity 160 to a logic circuit 106 are connected as a load to the input line 13 connected to the resistance change type element 15 in an on-state.

In the present example embodiment, the programmable output buffer 110 for which a drive power can be adjusted is connected to an input side of the input line 13. Then, the programmable output buffer 110 connected to each input line 13 is set to a drive power according to a number (also referred to as a fan-out number) of the output lines 14 connected to each input line 13. For example, in the programmable output buffer 110, a drive power is set to 1 time when a fan-out number of the input line 13 connected to the programmable output buffer 110 is 1, and a drive power is set to 3 times when the fan-out number is 3. In this way, stress resulting from an increase in a propagation delay and electromigration can be improved by adjusting a drive power of the programmable output buffer 110 according to a fan-out number of the input line 13.

FIG. 11 is a configuration diagram explicitly illustrating a connection relation between the programmable logic circuit 1 (FIG. 10) and the logic circuit group 16 included in a previous-stage circuit. As in FIG. 11, an output of the logic circuit group 16 of the previous-stage circuit is input to the programmable logic circuit 1. The output from the logic circuit group 16 of the previous-stage circuit is connected to an input terminal of the output buffer constituting the output buffer group 11.

Depending on a kind of a logic circuit, a number of output signals can become plural. For example, an output is one output when a logic circuit is an AND circuit or an OR circuit, but an output becomes multi-bit when a logic circuit is an arithmetic logic operation circuit. As in FIG. 11, logic circuits constituting the previous-stage logic circuit group 16 may be multi-bit outputs, or may be different kinds of logic circuits. Therefore, in the present example embodiment, the crossbar switch 12 is multi-input multi-output. When the crossbar switch 12 is multi-input multi-output, a configuration in which an output buffer is connected to each of a plurality of input lines 13 of the crossbar switch 12 is provided.

As described above, in the present example embodiment, current drive capability for an input line of a crossbar switch is made variable by providing an output buffer group on an input side of the crossbar switch. In the present example embodiment, an input capacity of the crossbar switch changes depending on an on/off state of a resistance change type element constituting the crossbar switch. An input capacity increases as connected to a greater number of elements in an on-state, but an increase in propagation time of a signal can be suppressed by increasing a drive power of a programmable output buffer according to an increase in an input capacity. Moreover, when a number of elements in an on-state is small, stress of electromigration on a resistance change type element can be suppressed by decreasing a drive power, without unnecessarily increasing incoming current.

### Modification Example

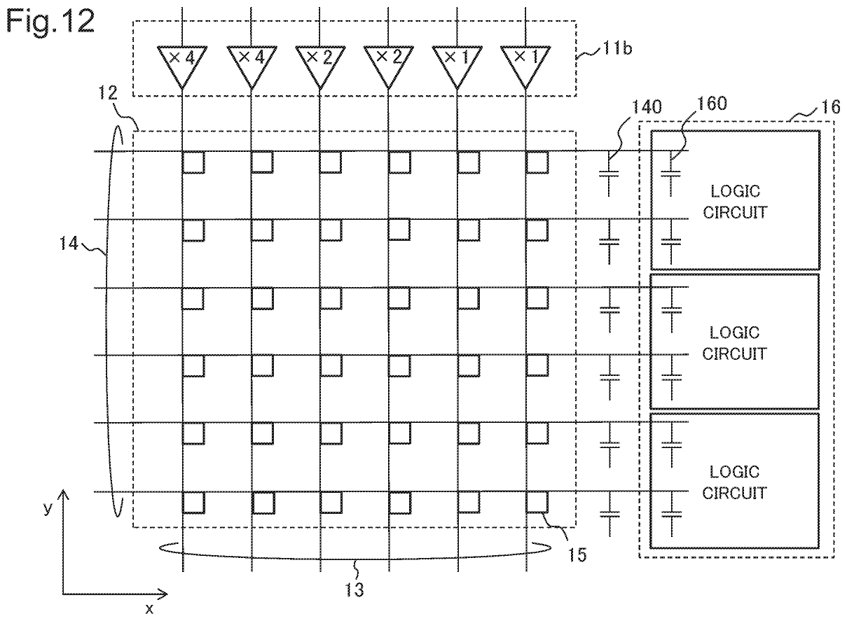

Herein, a modification example of the present example embodiment is described with reference to the drawings. FIG. 12 is a configuration example using an output buffer group 11b combining a plurality of output buffers having drive powers fixed to different values.

In the configuration of FIG. 12, the output buffer group 11b includes at least one output buffer for each of drive powers different from one another. FIG. 12 illustrates a number indicating a drive power for each of the output buffers constituting the output buffer group 11b. A signal having connection with a great fan-out number is preferentially allocated to the input line 13 connected to the output buffer having a high drive power. On the other hand, a signal having connection with a small fan-out number may be allocated to the input line 13 connected to the output buffer having a low drive power.

In the configuration of FIG. 12, a drive power of each of the output buffers constituting the output buffer group 11b is fixed, but stress resulting from an increase in a propagation delay and electromigration can be improved by selecting the input line 13 according to a fan-out number. In the configuration of FIG. 12, an increase in a layout area of the output buffer group 11b can be suppressed by separately producing, in advance, drive powers of a plurality of output buffers constituting the output buffer group 11b.

### Second Example Embodiment

Next, a programmable logic circuit according to a second example embodiment of the present invention is described with reference to the drawings. The present example embodiment is different from the first example embodiment in configuring a cluster structure by feeding back, to a crossbar switch circuit, an output of each of logic circuits constituting a logic circuit group. Hereinafter, description is suitably omitted with regard to a component similar to that in the first example embodiment.

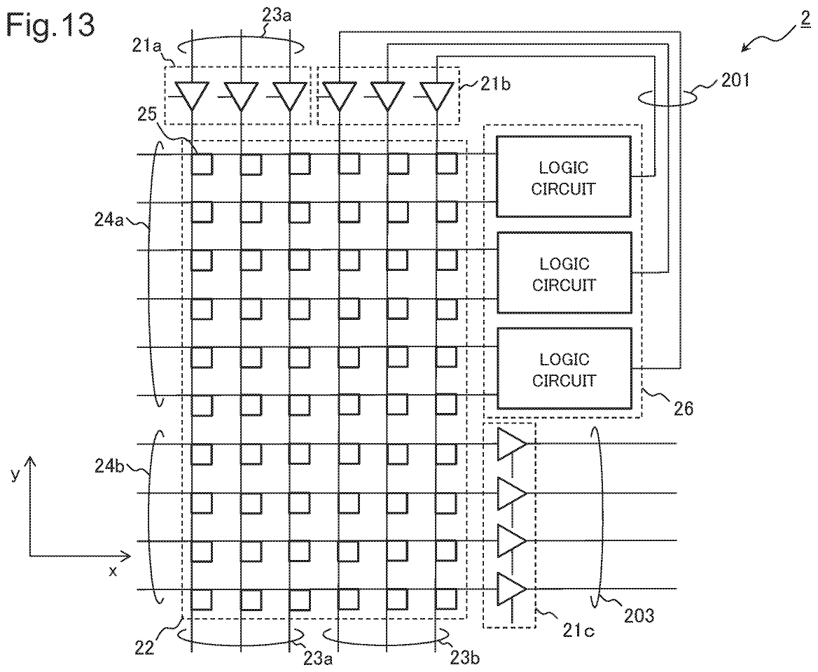

FIG. 13 is a conceptual diagram illustrating a configuration of a programmable logic circuit 2 according to the present example embodiment. Note that the programmable logic circuit 2 having the configuration of FIG. 13 is also referred to as a cluster structure. As in FIG. 13, the programmable logic circuit 2 includes a crossbar switch 22, a first output buffer group 21a, a second output buffer group 21b, and a logic circuit group 26. Note that a third output buffer group 21c is also illustrated in FIG. 13, but the third output buffer group 21c can be omitted.

The crossbar switch 22 is constituted of input lines (an input line 23a and an input line 23b) laid along a y-direction, output lines (an output line 24a and an output line 24b) laid along an x-direction, and a plurality of resistance change type elements 25 each placed at an intersection of the input line and the output line. Note that, in the present example embodiment, the input line 23a, the input line 23b, the output line 24a, and the output line 24b are described in this way, regardless of whether each of the lines is a single line or a multiple line.

The input line 23a is connected to any one of output buffers included in the first output buffer group 21a. The input line 23b is connected to any one of output buffers included in the second output buffer group 21b. Moreover, the input line 23a and the input line 23b are connected to either one of the output line 24a and the output line 24b via the resistance change type element 25.

The output line 24a and the output line 24b are connected to either one of the input line 23a and the input line 23b via the resistance change type element 25. The output line 24a is connected to any one of logic circuits constituting the logic circuit group 26. Moreover, the output line 24b is connected to an external output line 203 via the third output buffer group 21c.

The crossbar switch 22 is connected to the external output line 203 for outputting a signal to an adjacent crossbar switch circuit (not illustrated). Note that the external output line 203 outputs a signal via the third output buffer group 21c for providing a drive power according to a fan-out number of the adjacent crossbar switch circuit.

The first output buffer group 21a includes at least one output buffer. The output buffer included in the first output buffer group 21a includes an input terminal, an output terminal, and a drive power setting terminal. The input terminal of the output buffer of the first output buffer group 21a is connected to an output of the previous-stage logic circuit group 26. The output terminal of the output buffer of the first output buffer group 21a is connected to the input line 23a. The drive power setting terminal of the output buffer of the first output buffer group 21a is connected to a non-illustrated control device, and inputs a control signal for setting a drive power of the output buffer.

The second output buffer group 21b includes at least one output buffer. The output buffer included in the second output buffer group 21b includes an input terminal, an output terminal, and a drive power setting terminal. The input terminal of the output buffer of the second output buffer group 21b is connected to an output of the logic circuit group 26 via a feedback wire 201. The output terminal of the output buffer of the second output buffer group 21b is connected to the input line 23b. The drive power setting terminal of the output buffer of the second output buffer group 21b is connected to a non-illustrated control device, and inputs a control signal for setting a drive power of the output buffer of the second output buffer group 21b.

The logic circuit group 26 is connected to the output line 24a. A signal is input to the logic circuit group 26 via the resistance change type element 25 in an on-state. Moreover, the logic circuit group 26 is connected to the second output buffer group 21b via the feedback wire 201. Further, an output of the logic circuit group 26 is input to the crossbar switch 22 via the second output buffer group 21b.

According to the configuration illustrated in FIG. 13, the logic circuit group 26 inside the programmable logic circuit 2 (cluster structure) can be interconnected by the feedback wire 201. Thus, according to the configuration illustrated in FIG. 13, a larger-scale programmable logic circuit can be configured in the single programmable logic circuit 2. Herein, a fan-out number of the crossbar switch 22 in the feedback wire 201 can variously change depending on a user design. When a fan-out number of the crossbar switch 22 is large, an increase in a propagation delay can be suppressed by increasing a drive power of the first output buffer group 21a.

### [Cluster Structure]

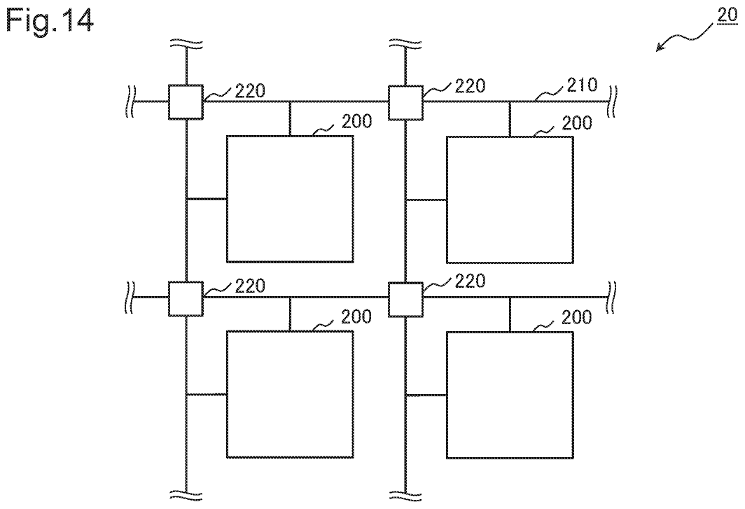

FIG. 14 is a conceptual diagram illustrating a configuration of a programmable logic circuit 20 in which cluster structures 200 having the configuration of the programmable logic circuit 2 in the present example embodiment are arranged in an array form.

The programmable logic circuit 20 is constituted of a plurality of the cluster structures 200 arranged in an array form, a segment wiring network 210 connecting the adjacent cluster structures 200, and a plurality of switch boxes 220 each disposed at an intersection of the segment wiring network 210.

The input line 23a (FIG. 13) of the crossbar switch 22 (FIG. 13) of the cluster structure 200 and the external output line 203 (FIG. 13) are connected to the segment wiring network 210. The adjacent cluster structures 200 are connected to one another via the switch box 220.

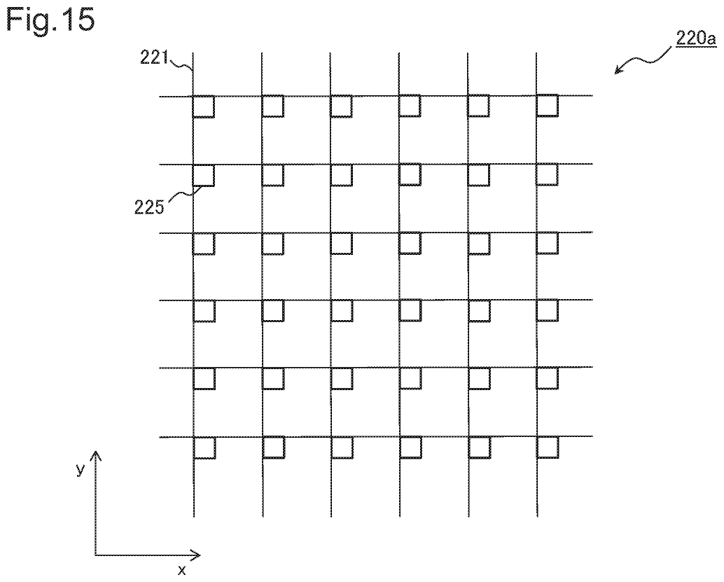

FIG. 15 is a switch box 220a being a configuration example of the switch box 220. The switch box 220a has a configuration which connects, by a resistance change type element 225, an intersection of a wiring network 221 constituted of wires spread in the x-direction and the y-direction. The switch box 220a can change a connection destination of the input line 23a.

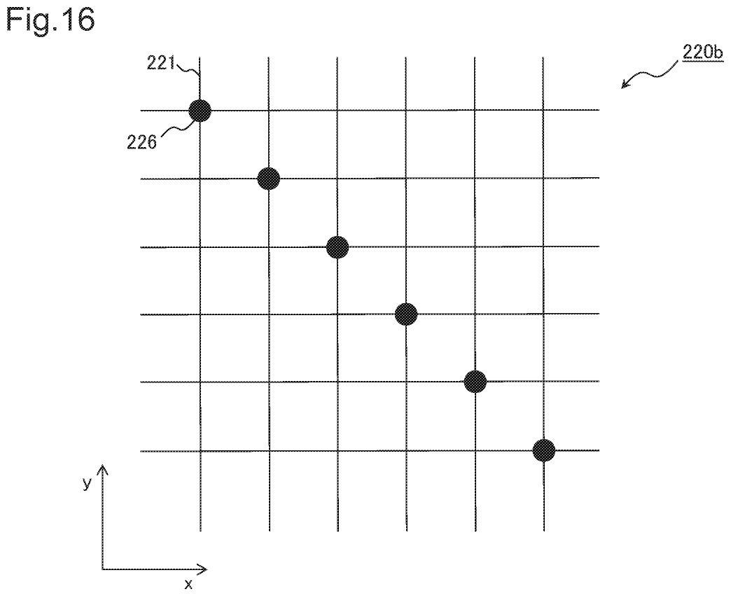

FIG. 16 is a switch box 220b being a configuration example of the switch box 220. The switch box 220b has a configuration which connects, by a via 226, an intersection of the wiring network 221 constituted of the wires spread in the x-direction and the y-direction. The intersection of the wiring network 221 is connected by the via 226, and therefore, the switch box 220b cannot change a connection destination of the input line 23a. The switch box 220b is used when a connection destination of the input line 23a is limited.

As described above, as in the first example embodiment, the present example embodiment can reduce a propagation delay and electromigration that can occur depending on a fan-out number, in a crossbar switch circuit using a resistance change type element. Moreover, the present example embodiment can configure a programmable logic circuit larger in scale than that in the first example embodiment, by arraying a cluster structure.

### Third Example Embodiment

Next, a programmable logic circuit according to a third example embodiment of the present invention is described with reference to the drawings. The present example embodiment is different from the second example embodiment in a configuration of each of logic circuits constituting a logic circuit group. Hereinafter, description is suitably omitted with regard to a component similar to that in the second example embodiment.

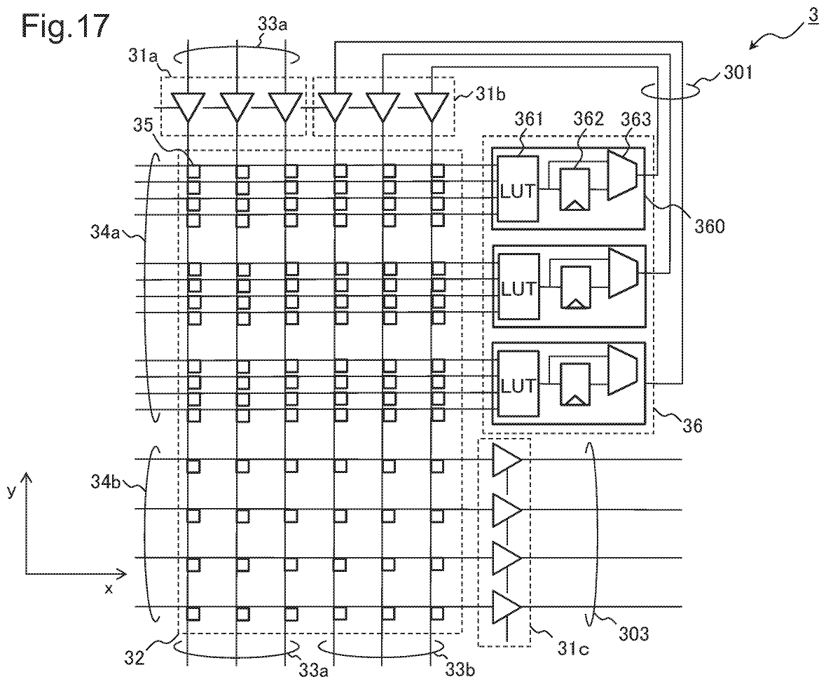

FIG. 17 is a conceptual diagram illustrating a configuration of a programmable logic circuit 3 in the present example embodiment. As in FIG. 17, the programmable logic circuit 3 includes a crossbar switch 32, a first output buffer group 31a, a second output buffer group 31b, and a logic circuit group 36. Note that a third output buffer group 31c is also illustrated in FIG. 17, but the third output buffer group 31c can be omitted.

The crossbar switch 32 is constituted of input lines (an input line 33a and an input line 33b) laid along a y-direction, output lines (an output line 34a and an output line 34b) laid along an x-direction, and a plurality of resistance change type elements 35 each placed at an intersection of the input line and the output line. Note that, in the present example embodiment, the input line 33a, the input line 33b, the output line 34a, and the output line 34b are described in this way, regardless of whether each of the lines is a single line or a multiple line.

The input line 33a is connected to any one of output buffers included in the first output buffer group 31a. The input line 33b is connected to any one of output buffers included in the second output buffer group 31b. Moreover, the input line 33a and the input line 33b are connected to either one of the output line 34a and the output line 34b via the resistance change type element 35.

The output line 34a and the output line 34b are connected to either one of the input line 33a and the input line 33b via the resistance change type element 35. The output line 34a is connected to any one of logic circuits 360 constituting the logic circuit group 36. Moreover, the output line 34b is connected to an external output line 303 via the third output buffer group 31c.

The crossbar switch 32 is connected to the external output line 303 for outputting a signal to an adjacent crossbar switch circuit (not illustrated). Note that the external output line 303 outputs a signal via the third output buffer group 31c for providing a drive power according to a fan-out number of the adjacent crossbar switch circuit. The third output buffer group 31c may have a configuration similar to those of the first output buffer group 31a and the second output buffer group 31b.

The first output buffer group 31a includes at least one output buffer. The output buffer included in the first output buffer group 31a includes an input terminal, an output terminal, and a drive power setting terminal. The input terminal of the output buffer of the first output buffer group 31a is connected to an output of the previous-stage logic circuit group 36. The output terminal of the output buffer of the first output buffer group 31a is connected to the input line 33a. The drive power setting terminal of the output buffer of the first output buffer group 31a is connected to a non-illustrated control device, and inputs a control signal for setting a drive power of the output buffer.

The second output buffer group 31b includes at least one output buffer. The output buffer included in the second output buffer group 31b includes an input terminal, an output terminal, and a drive power setting terminal. The input terminal of the output buffer of the second output buffer group 31b is connected to an output of the logic circuit group 36 via a feedback wire 301. The output terminal of the output buffer of the second output buffer group 31b is connected to the input line 33b. The drive power setting terminal of the output buffer of the second output buffer group 31b is connected to a non-illustrated control device, and inputs a control signal for setting a drive power of the output buffer of the second output buffer group 31b.

The logic circuit group 36 is connected to the output line 34a. A signal is input to the logic circuit group 36 via the resistance change type element 35 in an on-state. Moreover, the logic circuit group 36 is connected to the second output buffer group 31b via the feedback wire 301. Further, an output of the logic circuit group 36 is input to the crossbar switch 32 via the second output buffer group 31b.

The logic circuit group 36 includes at least one logic circuit 360. The logic circuit 360 includes a basic logic element having a lookup table circuit 361, a flip-flop circuit 362, and a multiplexer circuit 363. The logic circuit 360 includes a lookup table and a flip-flop, and configures a programmable synchronous logic circuit by rewriting data in the lookup table.

An output of the output line 34a of the crossbar switch 32 is input to the 4-input lookup table circuit 361. The lookup table circuit 361 outputs one signal by referring to a value of an internal memory from a set of a plurality of input signals input from the output line 34a.

An output of the lookup table circuit 361 is input to the flip-flop circuit 362. Outputs of the lookup table circuit 361 and the flip-flop circuit 362 are input to the multiplexer circuit 363. The multiplexer circuit 363 selects and then outputs any one of signals input from the lookup table circuit 361 and the flip-flop circuit 362. An output from the multiplexer circuit 363 becomes an output of the logic circuit 360.

The output of the logic circuit 360 is input, via the feedback wire 301, to any one of output buffers constituting the second output buffer group 31b. Then, the output of the logic circuit 360 is input to the crossbar switch 32 via any one of the output buffers constituting the second output buffer group 31b.

In the programmable logic circuit 3 in the present example embodiment, a plurality of basic logic elements can be connected to one another by the feedback wire 301. Thus, a larger-scale programmable logic circuit can be configured in the single programmable logic circuit 3. Moreover, the feedback wire 301 is also connected to the external output line 303. Thus, a larger-scale programmable logic circuit can be configured by arranging, in an array form, cluster structures formed by the programmable logic circuits 3.

As described above, the present example embodiment can improve circuit performance by decreasing an influence of a propagation delay dependent on a fan-out number of a crossbar switch having a resistance change type element, in a programmable logic circuit using a lookup table circuit.

### Fourth Example Embodiment

Next, a programmable logic circuit according to a fourth example embodiment of the present invention is described with reference to the drawings. The present example embodiment is different from the third example embodiment in that a drive power of each of output buffers constituting an output buffer group is fixed. Note that, hereinafter, description is suitably omitted with regard to a component similar to that in the third example embodiment.

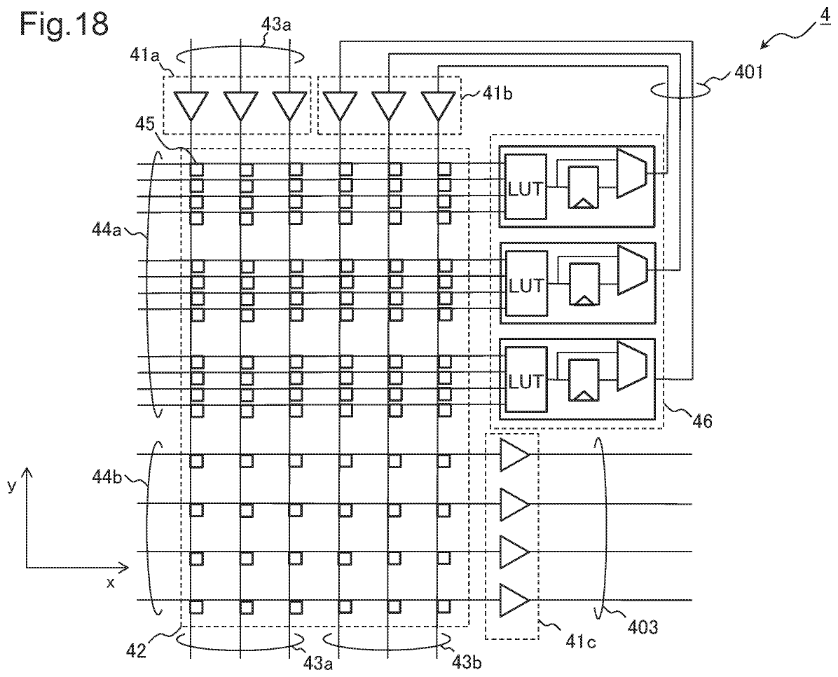

FIG. 18 is a conceptual diagram illustrating a configuration of a programmable logic circuit 4 in the present example embodiment. As in FIG. 18, the programmable logic circuit 4 includes a crossbar switch 42, a first output buffer group 41a, a second output buffer group 41b, and a logic circuit group 46. Note that a third output buffer group 41c is also illustrated in FIG. 18, but the third output buffer group 41c can be omitted.

The crossbar switch 42 is constituted of input lines (an input line 43a and an input line 43b) laid along a y-direction, output lines (an output line 44a and an output line 44b) laid along an x-direction, and a plurality of resistance change type elements 45 each placed at an intersection of the input line and the output line. Note that, in the present example embodiment, the input line 43a, the input line 43b, the output line 44a, and the output line 44b are described in this way, regardless of whether each of the lines is a single line or a multiple line.

The input line 43a is connected to any one of output buffers included in the first output buffer group 41a. The input line 43b is connected to any one of output buffers included in the second output buffer group 41b. Moreover, the input line 43a and the input line 43b are connected to either one of the output line 44a and the output line 44b via the resistance change type element 45.

The output line 44a and the output line 44b are connected to either one of the input line 43a and the input line 43b via the resistance change type element 45. The output line 44a is connected to any one of logic circuits constituting the logic circuit group 46. Moreover, the output line 44b is connected to an external output line 403 via the third output buffer group 41c.

The crossbar switch 42 is connected to the external output line 403 for outputting a signal to an adjacent crossbar switch circuit (not illustrated). Note that the external output line 403 outputs a signal via the third output buffer group 41c for providing a drive power according to a fan-out number of the adjacent crossbar switch circuit. The third output buffer group 41c may have a configuration similar to those of the first output buffer group 41a and the second output buffer group 41b.

The first output buffer group 41a includes at least two output buffers having drive powers different from each other. The output buffer included in the first output buffer group 41a includes an input terminal and an output terminal. The input terminal of the output buffer of the first output buffer group 41a is connected to an output of the previous-stage logic circuit group 46. The output terminal of the output buffer of the first output buffer group 41a is connected to the input line 43a.

The second output buffer group 41b includes at least two output buffers having drive powers different from each other. The output buffer included in the second output buffer group 41b includes an input terminal and an output terminal. The input terminal of the output buffer of the second output buffer group 41b is connected to an output of the logic circuit group 46 via a feedback wire 401. The output terminal of the output buffer of the second output buffer group 41b is connected to the input line 43b.

The logic circuit group 46 is connected to the output line 44a. A signal is input to the logic circuit group 46 via the resistance change type element 45 in an on-state. Moreover, the logic circuit group 46 is connected to the second output buffer group 41b via the feedback wire 401. Further, an output of the logic circuit group 46 is input to the crossbar switch 42 via the second output buffer group 41b. Note that a configuration and a function of a logic circuit included in the logic circuit group 46 are similar to those in the third example embodiment, and therefore, detailed description is omitted.

An output of the output line 44a of the crossbar switch 42 is input to a 4-input lookup table of any one of basic logic elements constituting the logic circuit group 46. An output of the lookup table is input to a flip-flop. Outputs of the lookup table and the flip-flop circuit are input to a multiplexer. The multiplexer selects and then outputs any one of signals input from the lookup table and the flip-flop. An output from the multiplexer becomes an output of the basic logic element.

The output of each of the basic logic elements constituting the logic circuit group 46 is input, via the feedback wire 401, to any one of output buffers constituting the second output buffer group 41b. Then, the output of the basic logic element is input to the crossbar switch 42 via any one of the output buffers constituting the second output buffer group 41b.

The basic logic element illustrated in the present example embodiment is a programmable logic. In a case of a configuration in which a plurality of basic logic elements are arranged, by determined a kind of the output buffer to be connected to a feedback wire in advance, a basic logic element connected to an output buffer having a high drive power can be allocated to a user logic having a great fan-out number at later. In this way, an output having a great fan-out number can be driven by an output buffer having a high drive power. Thus, even though no programmable output buffer is used as in the present example embodiment, an advantageous effect substantially similar to that in the third example embodiment can be acquired.

A programmable output buffer requires a layout area associated with a maximum drive power by being designed in consideration of the maximum drive power. In contrast, it is possible to decrease a layout area in association with each drive power by preparing, in advance, output buffers having different drive powers. Moreover, as compared with a case where output buffers having the same drive power are used, a drive power can be more greatly changed with an equal layout area.

As described above, the present example embodiment can make a layout area smaller than that in the third example embodiment, by utilizing a crossbar switch circuit with output buffers having different drive powers. Moreover, as in the third example embodiment, the present example embodiment can improve circuit performance by decreasing an influence of a propagation delay dependent on a fan-out number of a crossbar switch having a resistance change type element.

### Fifth Example Embodiment

Next, a semiconductor device according to a first example embodiment of the present invention is described with reference to the drawings. The semiconductor device in the present example embodiment is a programmable integrated circuit in which the programmable logic circuit in each of the first to fourth example embodiments is configured.

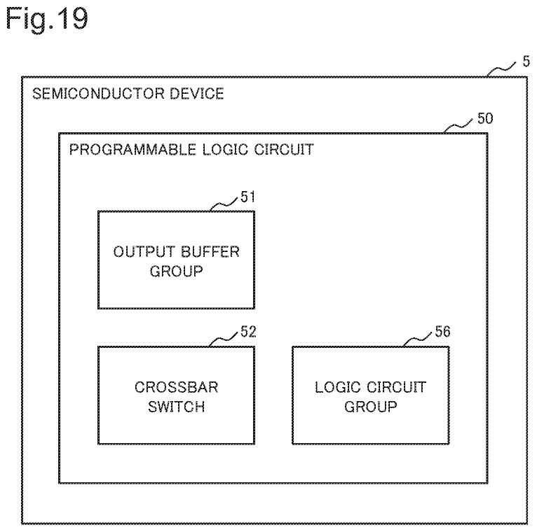

FIG. 19 is a block diagram illustrating a configuration of a semiconductor device 5 in the present example embodiment. The semiconductor device 5 includes a programmable logic circuit 50 (also referred to as a user circuit) having an output buffer group 51, a crossbar switch 52, and a logic circuit group 56.

The crossbar switch 52 is constituted of a plurality of first wires arranged in a first direction, a plurality of second wires arranged in a second direction intersecting the first direction, and a resistance change type element connecting the first wires and the second wires.

The output buffer group 51 is constituted of at least two output buffers operating with different drive powers. The output buffers constituting the output buffer group 51 are connected to an input side of any one of the plurality of first wires.

The logic circuit group 56 is constituted of at least one logic circuit connected to an output of the second wire.

The programmable logic circuit in the present example embodiment can reduce a propagation delay and electromigration that can occur depending on a fan-out number, in a crossbar switch circuit using a resistance change type element.

The semiconductor device in the present example embodiment is not limited to a circuit configuration using a crossbar circuit. For example, the semiconductor device in the present example embodiment can be configured as a semiconductor device having a memory circuit such as a dynamic random access memory (DRAM) or a static random access memory (SRAM). Moreover, the semiconductor device in the present example embodiment can be configured as a semiconductor device having a ferro electric random access memory (FeRAM) or a magnetic random access memory (MRAM). Further, the semiconductor device in the present example embodiment can be configured as a semiconductor device having a flash memory or a bipolar transistor. Further, the semiconductor device in the present example embodiment can be configured as a semiconductor device having a logic circuit such as a microprocessor. Further, the semiconductor device in the present example embodiment can also be applied to a wire of a substrate, a package, or the like in which the memory circuit and logic circuit as described above are consolidated.

### Sixth Example Embodiment

Next, a control device in a sixth example embodiment of the present invention is described with reference to the drawings. The control device in the present example embodiment generates configuration data of the programmable logic circuit 3 in the third example embodiment, and implements the programmable logic circuit 3 in a programmable logic circuit, based on the generated configuration data.

### (Configuration)

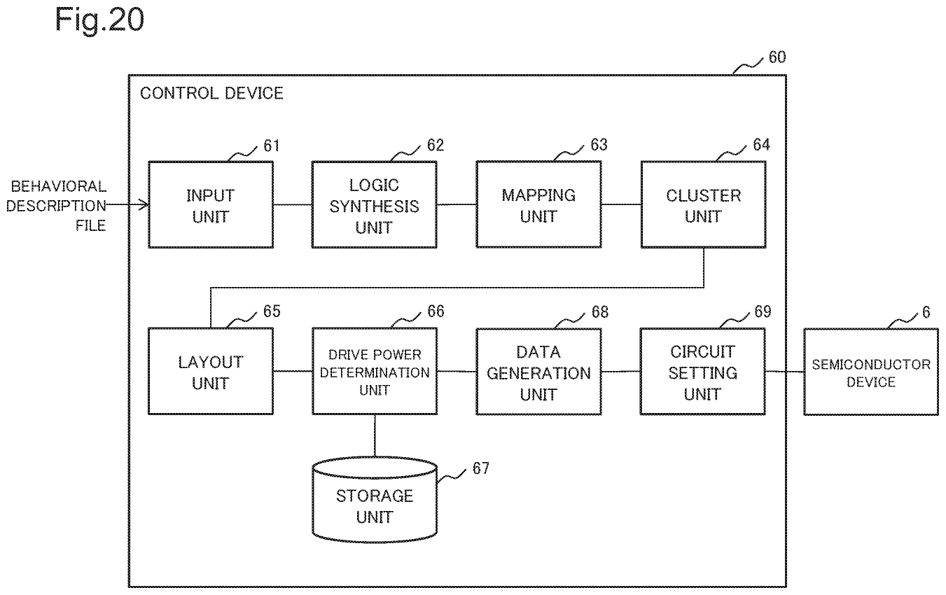

FIG. 20 is a block diagram illustrating a configuration of a control device 60 in the present example embodiment. As in FIG. 20, the control device 60 includes an input unit 61, a logic synthesis unit 62, a mapping unit 63, a cluster unit 64, a layout unit 65, a drive power determination unit 66, a storage unit 67, a data generation unit 68, and a circuit setting unit 69. The control device 60 is connected to a semiconductor device 6 (also referred to as a programmable integrated circuit) having a configuration similar to that of the semiconductor device 5 in the fifth example embodiment.

The input unit 61 inputs a behavioral description file of a user circuit generated by a designer. For example, a behavioral description file is generated by use of a hardware description language such as Verilog-hardware description language (Verilog-HDL) or very high-speed integrated circuit HDL (VHDL). The input unit 61 outputs the input behavioral description file to the logic synthesis unit 62.

A behavioral description file is input to the logic synthesis unit 62 from the input unit 61. The logic synthesis unit 62 generates a gate-level net list (also referred to as a first-level net list) based on a user circuit by logically synthesizing the input behavioral description file. The logic synthesis unit 62 generates a gate-level net list by use of a basic logic circuit included in the semiconductor device 6. The logic synthesis unit 62 optimizes a circuit in such a way as to satisfy timing limitation information set by a designer in advance. The logic synthesis unit 62 outputs the generated gate-level net list to the mapping unit 63.

A gate-level net list is input to the mapping unit 63 from the logic synthesis unit 62. The mapping unit 63 optimizes the net list in such a way as to satisfy timing limitation information set by a designer in advance. In other words, the mapping unit 63 maps a gate-level net list based on a user circuit, and converts the gate-level net list into a lookup table (LUT) level net list (also referred to as a second-level net list). The mapping unit 63 outputs, to the cluster unit 64, the net list converted into the LUT level.

An LUT-level net list is input to the cluster unit 64 from the mapping unit 63. The cluster unit 64 groups a plurality of LUTs and flip-flops, and generates a technology-level net list (also referred to as a third-level net list) adapted to a configuration of clustered basic logic circuits included in an actual programmable logic circuit. The cluster unit 64 outputs the generated technology-level net list to the layout unit 65.

A technology-level net list is input to the layout unit 65 from the cluster unit 64. The layout unit 65 calculates an optimum layout of the technology-level net list for an array of clustered basic logic circuits. Then, the layout unit 65 connects a crossbar circuit connected to the clustered basic logic circuits, and performs wiring inside and outside a cluster. In other words, the layout unit 65 executes arrangement and wiring processing of a programmable logic circuit to be implemented in the semiconductor device 6, and generates configuration information of the programmable logic circuit. The layout unit 65 outputs the generated configuration information of the programmable logic circuit to the drive power determination unit 66.

Configuration information of a programmable logic circuit is input to the drive power determination unit 66 from the layout unit 65. The drive power determination unit 66 calculates a fan-out number of a crossbar from the configuration information of the programmable logic circuit. The drive power determination unit 66 refers to a reference table saved in the storage unit 67, and calculates a drive power of a programmable output buffer according to the calculated fan-out number. In other words, the drive power determination unit 66 optimizes a drive power of a programmable output buffer according to a fan-out number of a crossbar. The drive power determination unit 66 outputs, to the data generation unit 68, the configuration information of the programmable logic circuit including the calculated drive power of the programmable output buffer.

The storage unit 67 stores a reference table in which a value of a drive power of a programmable output buffer associated with a fan-out number of a crossbar is saved. The reference table saved in the storage unit 67 stores a condition which increases a drive power of a programmable output buffer in such a way that a delay time decreases when a fan-out number is large within a range satisfying a criterion for electromigration of a resistance change type element.

Configuration information of a programmable logic circuit including a drive power of a programmable output buffer is input to the data generation unit 68 from the drive power determination unit 66. The data generation unit 68 generates, based on the configuration information, configuration data for programming a programmable logic circuit into the semiconductor device 6. The data generation unit 68 outputs the generated configuration data to the circuit setting unit 69.

Configuration data are input to the circuit setting unit 69 from the data generation unit 68. The circuit setting unit 69 programs a programmable logic circuit into the semiconductor device 6, based on the configuration data.

The above is description of the configuration of the control device 60. Next, an operation of the control device 60 is described.

### (Operation)

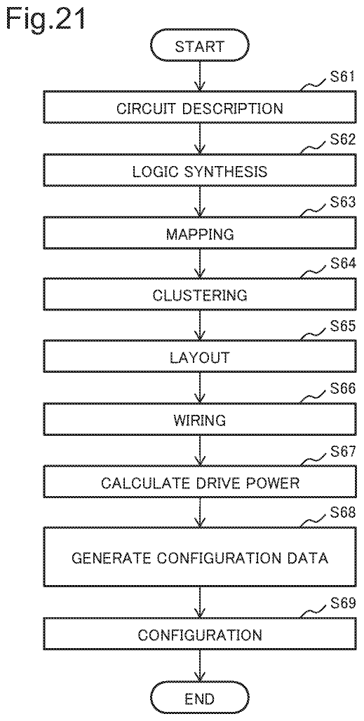

FIG. 21 is a flowchart for describing an operation of the control device 60 in the present example embodiment. In description along the flowchart of FIG. 21, the control device 60 is described as an operation agent.

In FIG. 21, first, a behavioral description file of a user circuit is input to the control device 60 (step S61).

Next, the control device 60 generates a first-level net list by logically synthesizing the behavioral description file (step S62).

Next, the control device 60 converts the first-level net list into a second-level net list by mapping the first-level net list (step S63).

Next, the control device 60 groups a plurality of logic elements composed of a plurality of LUTs and flip-flops included in the second-level net list, and generates a third-level net list adapted to a configuration of clustered basic logic elements (step S64).

Next, the control device 60 calculates an optimum layout of the third-level net list for an array of clustered basic logic elements (step S65).

Next, the control device 60 connects a crossbar switch connected to the clustered basic logic circuits, and performs wiring inside and outside a cluster (step S66). Through steps S65 and S66, configuration information of a user circuit is generated.

Next, the control device 60 calculates a fan-out number for each input of a crossbar switch, based on the configuration information of the user circuit, and determines a drive power of a programmable output buffer according to the fan-out number (step S67).

Next, the control device 60 generates, based on the configuration information of the user circuit including the drive power of the output buffer, configuration data for programming a user circuit into the semiconductor device 6 (step S68).

Then, the control device 60 programs the user circuit into the semiconductor device 6, based on the configuration data.

The above is description of the operation of the control device 60 along the flowchart of FIG. 21. Through the processing along the flowchart of FIG. 21, a programmable integrated circuit is set to a programmable logic circuit which achieves circuit description of a user.

As described above, the present example embodiment can implement a programmable logic circuit which achieves circuit description of a user, in a programmable integrated circuit including a resistance change type element at an intersection of a crossbar switch circuit. In other words, the present example embodiment can generate, according to a fan-out number of a crossbar switch, a configuration pattern with an increased drive power of a buffer connected to a crossbar input to which a signal having connection with a great fan-out number is input. The programmable logic circuit implemented by the control device in the present example embodiment can improve an increase in a propagation delay, and improve stress resulting from electromigration of a resistance change type element.

### Seventh Example Embodiment

Next, a control device in a seventh example embodiment of the present invention is described with reference to the drawings. The control device in the present example embodiment generates configuration data of the programmable logic circuit 4 in the fourth example embodiment, and implements the programmable logic circuit 4 in a programmable logic circuit, based on the generated configuration data.

### (Configuration)

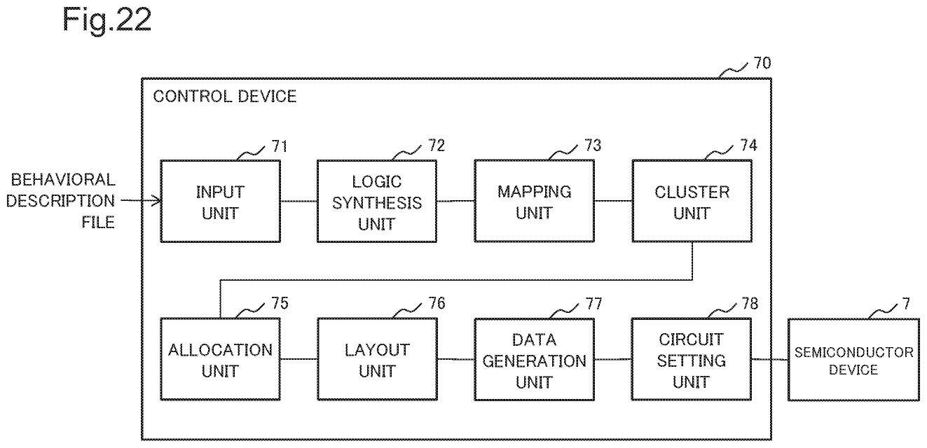

FIG. 22 is a block diagram illustrating a configuration of a control device 70 in the present example embodiment. As in FIG. 22, the control device 70 includes an input unit 71, a logic synthesis unit 72, a mapping unit 73, a cluster unit 74, an allocation unit 75, a layout unit 76, a data generation unit 77, and a circuit setting unit 78. The control device 60 is connected to a semiconductor device 7 (also referred to as a programmable integrated circuit) having a configuration similar to that of the semiconductor device 5 in the fifth example embodiment.

The input unit 71 inputs a behavioral description file of a user circuit generated by a designer. The input unit 71 has a configuration similar to that of the input unit 61 in the sixth example embodiment. The input unit 71 outputs the input behavioral description file to the logic synthesis unit 72.

A behavioral description file is input to the logic synthesis unit 72 from the input unit 71. The logic synthesis unit 72 has a configuration similar to that of the logic synthesis unit 62 in the sixth example embodiment. The logic synthesis unit 72 generates a gate-level net list (also referred to as a first-level net list) based on a user circuit by logically synthesizing the input behavioral description file. The logic synthesis unit 72 outputs the generated gate-level net list to the mapping unit 73.

A gate-level net list is input to the mapping unit 73 from the logic synthesis unit 72. The mapping unit 73 has a configuration similar to that of the mapping unit 63 in the sixth example embodiment. The mapping unit 73 maps a gate-level net list based on a user circuit, and converts the gate-level net list into an LUT-level net list (also referred to as a second-level net list). The mapping unit 73 outputs, to the cluster unit 74, the net list converted into the LUT level.

An LUT-level net list is input to the cluster unit 74 from the mapping unit 73. The cluster unit 74 has a configuration similar to that of the cluster unit 64 in the sixth example embodiment. The cluster unit 74 groups a plurality of LUTs and flip-flops, and generates a technology-level net list (also referred to as a third-level net list) adapted to a configuration of clustered basic logic circuits included in an actual programmable logic circuit. The cluster unit 74 outputs the generated technology-level net list to the allocation unit 75.

A technology-level net list is input to the allocation unit 75 from the cluster unit 74. The allocation unit 75 calculates a fan-out number of a crossbar from the technology-level net list, and performs re-clustering of allocating the crossbar to a basic logic element circuit connected to an output buffer having a high drive power, in a descending order of the fan-out numbers. The allocation unit 75 outputs the re-clustered technology-level net list to the layout unit 76.

A re-clustered technology-level net list is input to the layout unit 76 from the allocation unit 75. The layout unit 76 calculates an optimum layout of the technology-level net list for an array of re-clustered basic logic circuits. Then, the layout unit 76 connects a crossbar circuit connected to the re-clustered basic logic circuits, and performs wiring inside and outside a cluster. In other words, the layout unit 76 executes arrangement and wiring processing of a programmable logic circuit to be implemented in the semiconductor device 7, and generates configuration information of the programmable logic circuit. The layout unit 76 outputs the generated configuration information of the programmable logic circuit to the data generation unit 77.

Configuration information of a programmable logic circuit including a drive power of a programmable output buffer is input to the data generation unit 77 from the layout unit 76. The data generation unit 77 has a configuration similar to that of the data generation unit 68 in the sixth example embodiment. The data generation unit 77 generates, based on the configuration information, configuration data for programming a programmable logic circuit into the semiconductor device 7. The data generation unit 77 outputs the generated configuration data to the circuit setting unit 78.

Configuration data are input to the circuit setting unit 78 from the data generation unit 77. The circuit setting unit 78 has a configuration similar to that of the circuit setting unit 69 in the sixth example embodiment. The circuit setting unit 78 programs a programmable logic circuit into the semiconductor device 7, based on the configuration data.

The above is description of the configuration of the control device 70. Next, an operation of the control device 70 is described.

### (Operation)

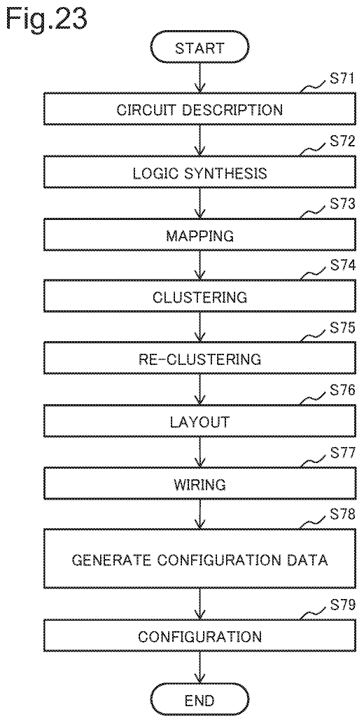

FIG. 23 is a flowchart for describing an operation of the control device 70 in the present example embodiment. In description along the flowchart of FIG. 23, the control device 70 is described as an operation agent.

In FIG. 23, first, a behavioral description file of a user circuit is input to the control device 70 (step S71).

Next, the control device 70 generates a first-level net list by logically synthesizing the behavioral description file (step S72).

Next, the control device 70 converts the first-level net list into a second-level net list by mapping the first-level net list (step S73).

Next, the control device 70 groups a plurality of logic elements composed of a plurality of LUTs and flip-flops included in the second-level net list, and generates a third-level net list adapted to a configuration of clustered basic logic elements (step S74).

Next, the control device 70 calculates a fan-out number for each input of a crossbar switch, based on the third-level net list. Then, the control device 70 re-clusters basic logic elements by allocating output buffers having high drive powers to the input of the crossbar switch, in a descending order of the fan-out numbers (step S75).

Next, the control device 70 calculates an optimum layout of the third-level net list for an array of re-clustered basic logic circuits (step S76).

Next, the control device 70 connects a crossbar switch connected to the re-clustered basic logic circuits, and performs wiring inside and outside a cluster (step S77). Through steps S76 and S77, configuration information of a user circuit is generated.

Next, the control device 70 generates, based on the configuration information of the user circuit including the allocation of the output buffers, configuration data for programming a user circuit into the semiconductor device 7 (step S78).

Then, the control device 70 programs the user circuit into the semiconductor device 7, based on the configuration data.

The above is description of the operation of the control device 70 along the flowchart of FIG. 23. Through the processing along the flowchart of FIG. 23, a programmable integrated circuit is set to a programmable logic circuit which achieves circuit description of a user.

The processing along the flowchart of FIG. 23 is applied to a programmable logic circuit having an output buffer group combining a plurality of output buffers in which drive powers are fixed. The processing along the flowchart of FIG. 23 refers to a technology-level net list, and preferentially allocates a basic logic circuit having an output buffer with a high drive power to a net having a great fan-out number.

As described above, the present example embodiment can implement a programmable logic circuit which achieves circuit description of a user, in a programmable integrated circuit including a resistance change type element at an intersection of a crossbar switch circuit. In other words, the present example embodiment can generate, according to a fan-out number of a crossbar switch, a configuration pattern which preferentially allocates a signal having connection with a great fan-out number to a crossbar input having a buffer with high drive capability. The programmable logic circuit implemented by the control device in the present example embodiment can improve an increase in a propagation delay, and improve stress resulting from electromigration of a resistance change type element.

### (Hardware)

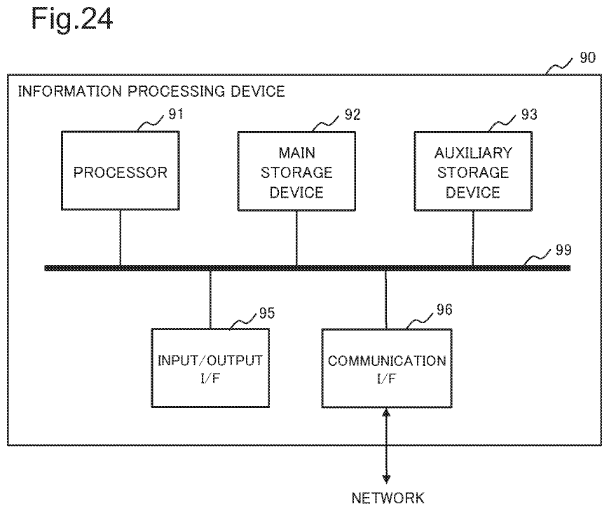

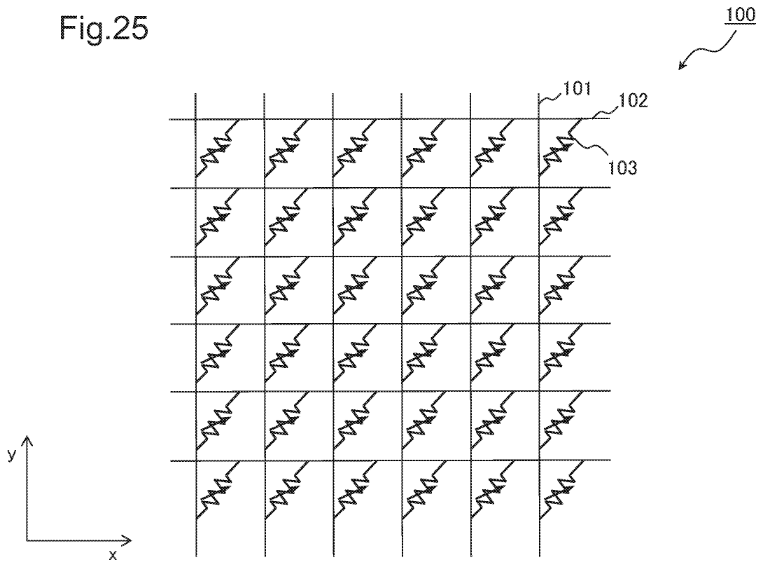

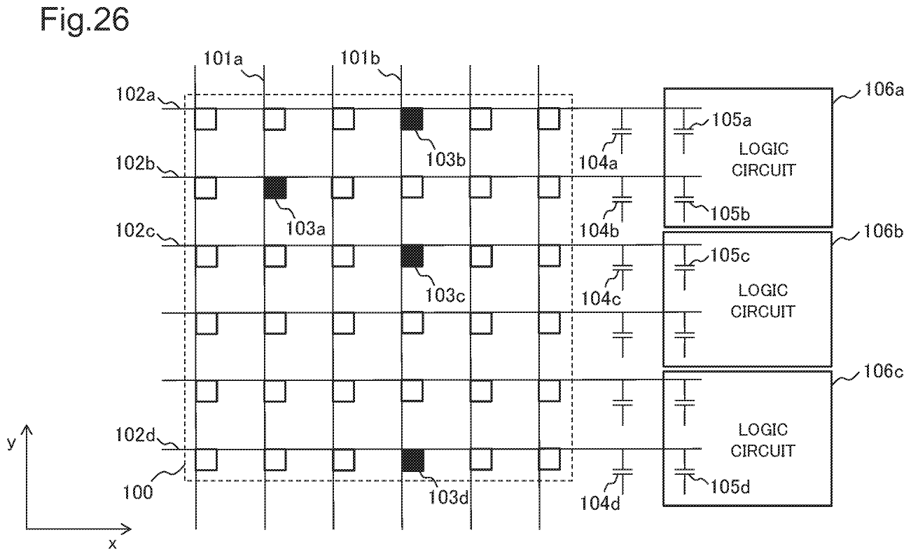

Herein, a hardware configuration which achieves the control device according to the sixth and seventh example embodiments of the present invention is described by citing an information processing device 90 in FIG. 24 as an example. Note that the information processing device 90 in FIG. 24 is a configuration example for achieving the control device in each example embodiment, and does not limit the scope of the present invention.

As in FIG. 24, the information processing device 90 includes a processor 91, a main storage device 92, an auxiliary storage device 93, an input/output interface 95, and a communication interface 96. In FIG. 24, an interface is abbreviated as an I/F. The processor 91, the main storage device 92, the auxiliary storage device 93, the input/output interface 95, and the communication interface 96 are data-communicably connected to one another via a bus 99. Moreover, the processor 91, the main storage device 92, the auxiliary storage device 93, and the input/output interface 95 are connected to a network such as the Internet or an intranet via the communication interface 96.

The processor 91 extracts a program saved in the auxiliary storage device 93 or the like into the main storage device 92, and executes the extracted program. In the present example embodiment, a configuration using a software program installed in the information processing device 90 may be provided. The processor 91 executes processing by the control device according to the present example embodiment.

The main storage device 92 has a region where a program is extracted. The main storage device 92 may be a volatile memory such as a dynamic random access memory (DRAM). Moreover, a non-volatile memory such as a magnetoresistive random access memory (MRAM) may be configured and added as the main storage device 92.

The auxiliary storage device 93 stores various data. The auxiliary storage device 93 is constituted of a local disk such as a hard disk or a flash memory. Note that the main storage device 92 can be configured to store various data, and the auxiliary storage device 93 can be omitted.

The input/output interface 95 is an interface for connecting the information processing device 90 and peripheral equipment. The communication interface 96 is an interface for connecting to an external system or a device through a network such as the Internet or an intranet, based on a standard or a specification. The input/output interface 95 and the communication interface 96 may be formed into a common interface as an interface for connecting to an external device.

The information processing device 90 may be configured in such a way that input equipment such as a keyboard, a mouse, and a touch panel is connected to the information processing device 90 as required. The input equipment is used for input of information and setting. Note that, when a touch panel is used as input equipment, a display screen of display equipment may be configured to double as an interface of the input equipment. Data communication between the processor 91 and input equipment may be mediated by the input/output interface 95.

Furthermore, the information processing device 90 may be equipped with display equipment for displaying information. When equipped with display equipment, the information processing device 90 preferably includes a display control device (not illustrated) for controlling display of the display equipment. The display equipment may be connected to the information processing device 90 via the input/output interface 95.

Furthermore, the information processing device 90 may be equipped with a disk drive as required. The disk drive is connected to the bus 99. Between the processor 91 and a non-illustrated recording medium (program recording medium), the disk drive mediates reading of data and a program from the recording medium, writing of a processing result of the information processing device 90 into the recording medium, and the like. The recording medium can be achieved by an optical recording medium such as a compact disc (CD) or a digital versatile disc (DVD). Additionally, the recording medium may be achieved by a semiconductor recording medium such as a universal serial bus (USB) memory or a secure digital (SD) card, a magnetic recording medium such as a flexible disk, or another recording medium.

The above is one example of a hardware configuration for enabling the control device according to each example embodiment of the present invention. Note that the hardware configuration in FIG. 24 is one example of a hardware configuration for executing arithmetic processing of the control device according to each example embodiment, and does not limit the scope of the present invention. Moreover, a program which causes a computer to execute processing relating to the control device according to each example embodiment also falls within the scope of the present invention. Further, a program recording medium recording a program according to each example embodiment also falls within the scope of the present invention.

The components of the control device in each example embodiment can be combined in any way. Moreover, the component of the control device in each example embodiment may be achieved by software, or may be achieved by a circuit.

While the present invention has been described above with reference to the example embodiments, the present invention is not limited to the above-described example embodiments. Various changes which can be understood by a person skilled in the art can be made to a configuration and details of the present invention within the scope of the present invention.

This application is based upon and claims the benefit of priority from Japanese Patent Application No. 2017-182576, filed on Mar. 22, 2017, the disclosure of which is incorporated herein in its entirety by reference.

### REFERENCE SIGNS LIST

1, 2, 3, 4, 20, 50 Programmable logic circuit
5, 6, 7 Semiconductor device
11, 51 Output buffer group
12, 22, 32, 42, 52 Crossbar switch
13, 23a, 23b, 33a, 33b, 43a, 43b Input line
14, 24a, 24b, 34a, 34b, 44a, 44b Output line
15, 25, 35, 45 Resistance change type element
16, 26, 36, 46, 56 Logic circuit group
21a, 31a, 41a First output buffer group
21b, 31b, 41b Second output buffer group
21c, 31c, 41c Third output buffer group
110 Programmable output buffer
111 Buffer circuit
112 Tristate buffer circuit
117 Input terminal
118 Output terminal
119 Drive power setting terminal
140 Capacity
160 Input capacity
151 Unipolar type element
152 Bipolar type element
153 Resistance change type element
200 Cluster structure
201, 301, 401 Feedback wire
203, 303, 403 External output line
210 Segment wiring network
220 Switch box
225 Resistance change type element
226 Via
360 Logic circuit
361 Lookup table circuit
362 Flip-flop circuit
363 Multiplexer circuit

What is claimed is:

1. A programmable integrated circuit comprising:
a crossbar switch constituted of a plurality of first wires arranged in a first direction, a plurality of second wires arranged in a second direction intersecting the first direction, and resistance change type elements connecting the first wires and the second wires;
an output buffer group constituted of at least two output buffers operating with different drive powers; and
a logic circuit group constituted of at least one logic circuit connected to an output of the second wire, wherein
the output buffer in the output buffer group is
connected to an input of any one of a plurality of the first wires.

2. The programmable integrated circuit according to claim 1, wherein
a plurality of the second wires include
an inward wire group constituted of a feedback wire connected to any one of the logic circuits constituting the logic circuit group, and an outward wire group constituted of a wire connected to an adjacent circuit, and
the output buffer group includes
a first output buffer group which inputs an output of the adjacent circuit, and
a second output buffer group which inputs, via the feedback wire, outputs of the logic circuits constituting the logic circuit group.

3. The programmable integrated circuit according to claim 2, wherein
the logic circuit includes
a lookup table which inputs a set of a plurality of input signals input from the inward wire group, and outputs one signal by referring to a value of an internal memory,
a flip-flop which inputs an output of the lookup table, and outputs any signal, and
a basic logic element constituted of a multiplexer which inputs outputs of the lookup table and the flip-flop, and selects and then outputs any signal, and
outputs a signal selected by the multiplexer to the second output buffer group via the feedback wire.

4. The programmable integrated circuit according to claim 2, further comprising
a third output buffer group constituted of at least two of the output buffers operating with different drive powers, wherein
the output buffers constituting the third output buffer group are
connected to any of wires constituting the outward wire group.

5. The programmable integrated circuit according to claim 1, wherein
the output buffer includes
an input terminal to which an input signal is input,
an output terminal connected to the first wire, and
an enable terminal which inputs a control signal for setting a value of a drive power.

6. The programmable integrated circuit according to claim 5, wherein
the output buffer includes
at least one buffer circuit, and
at least one tristate buffer circuit sharing an input and an output with the buffer circuit, and being set a drive power according to the control signal input from the enable terminal.

7. The programmable integrated circuit according to claim 1, wherein
the output buffer group has
a configuration combining the output buffers fixed to different drive powers.

8. A circuit being configured by arranging, in an array form on a segment wiring network in which a switch box is disposed at an intersection, a plurality of cluster structures each having a configuration of a user circuit configured in the programmable integrated circuit according to claim 3.

9. A control device programming a user circuit into a programmable integrated circuit which includes a crossbar switch, an output buffer connected to an input of the crossbar switch and having at least two variable drive powers, and at least one logic circuit connected to any one of outputs of the crossbar switch, and has a configuration in which an output of the logic circuit is fed back to any one of the output buffers, the control device comprising:
at least one memory storing instructions; and
at least one processor connected to the at least one memory and configured to execute the instructions to:
input a behavioral description file of the user circuit;
generate a first-level net list by logically synthesizing the behavioral description file;
convert the first-level net list into a second-level net list by mapping the first-level net list;
group a plurality of logic elements included in the second-level net list, and generate a third-level net list adapted to a configuration of clustered basic logic elements;
generate configuration information of the user circuit by calculating optimum disposition of the third-level net list for an array of the clustered basic logic elements, connect the crossbar switch connected to the clustered basic logic elements, and then performing wiring inside and outside a cluster;
store a reference table saving a value of a drive power of the output buffer associated with a fan-out number of the crossbar switch;
calculate the fan-out number for each input of the crossbar switch, based on the configuration information of the user circuit, and determine a drive power of the output buffer associated with the fan-out number by referring to the reference table;
generate configuration data for programming the user circuit into the programmable integrated circuit, based on the configuration information of the user circuit including a drive power of the output buffer; and
program the user circuit into the programmable integrated circuit, based on the configuration data.

10. A control device programming a user circuit into a programmable integrated circuit which includes a crossbar switch, an output buffer connected to an input of the crossbar switch and having at least two fixed drive powers, and at least one logic circuit connected to any one of outputs of the crossbar switch, and has a configuration in which an output of the logic circuit is fed back to any one of the output buffers, the control device comprising:
at least one memory storing instructions; and
at least one processor connected to the at least one memory and configured to execute the instructions to:
input a behavioral description file of the user circuit;
generate a first-level net list by logically synthesizing the behavioral description file;
convert the first-level net list into a second-level net list by mapping the first-level net list;
group a plurality of logic elements included in the second-level net list, and generate a third-level net list adapted to a configuration of clustered basic logic circuits;
re-cluster the basic logic circuit by calculating a fan-out number for each input of the crossbar switch, based on the third-level net list, and allocate the output buffers having high drive powers to an input of the crossbar switch in a descending order of fan-out numbers;
generate configuration information of the user circuit by calculating optimum disposition of the third-level net list for an array of the re-clustered basic logic circuits, connect the crossbar switch connected to the re-clustered basic logic circuits, and then perform wiring inside and outside a cluster;
generate configuration data for programming the user circuit into the programmable integrated circuit, based on configuration information of the user circuit including allocation of the output buffers; and
program the user circuit into the programmable integrated circuit, based on the configuration data.
